(19) United States
(12) Patent Application Publication
(10) Pub. No.: US 2004/0120419 A1
(43) Pub. Date: Jun. 24, 2004

(54) I/O channel equalization based on low-frequency loss insertion

(76) Inventors: Claude R. Gauthier, Cupertino, CA (US); Aninda K. Roy, San Jose, CA (US)

Correspondence Address: OSHA & MAY L.L.P./SUN, 1221 MCKINNEY, SUITE 2800, HOUSTON, TX, 77010, US

(21) Appl. No.: 10/324,421

(22) Filed: Dec. 20, 2002

(51) Int. Cl. H04B 15/00; H03H 7/00

(52) U.S. Cl. 375/285; 333/167

(57) ABSTRACT

A method and apparatus for transmitting a data signal is provided. A transmitter is arranged to transmit the data signal on a transmission line disposed on a printed circuit board. A filter is operatively connected to the transmission line such that the filter is arranged to attenuate a low frequency signal component of the data signal.

### BACKGROUND OF INVENTION

As shown in FIG. 1, a common computer system (100) includes a central processing unit (CPU) (102), memory (104), and numerous other elements and functionalities (not shown) typical of computers. The computer (100) may also include input means, such as a keyboard (106) and a mouse (108), and output devices, such as a monitor (110). Those skilled in the art will understand that these input and output means may take other forms in an accessible environment. In one or more embodiments of the invention, the computer system may have multiple processors and may be configured to handle multiple tasks.

The CPU (102) is an integrated circuit (IC) and is typically one of many integrated circuits included in the computer (100). Integrated circuits may perform operations on data and transmit resulting data to other integrated circuits. The correct operation of the computer relies on accurate transmission of data between integrated circuits.

FIG. 2 shows a block diagram of a conventional system for transmitting data signals between two integrated circuits (202, 204). Data signals are transmitted from a transmitting IC (202) to a receiving IC (204) along a transmission line (210). Data signals may also be transmitted to other receiving ICs (not shown). Impedances (206, 208) represent parasitic impedances of the transmission line. The impedances (206, 208) may include resistive, capacitive, and inductive elements. The impedances (206, 208) of the transmission line (210) determine the effects the transmission line (210) has on transmitted data signals.

A total impedance of the transmission line (210) is determined by the series impedance (206) and the shunt impedance (208) of the transmission line. The total impedance of the transmission line is dependant on a frequency of a data signal on the transmission line. Due to voltage divider effects, as the total impedance of the transmission line increases, a magnitude of the data signal on the transmission line decreases. This decrease in magnitude is called attenuation. The total impedance of the transmission line may increase as the frequency of the data signal on the transmission line increases.

FIG. 3 shows a graph of a typical transmission line's impedance characteristic (302). Because impedance and signal magnitude are correlated, the impedance of a line may be used to determine a relationship between a magnitude of a data signal input to the line and an magnitude of a data signal output from the line. The relationship between input and output signal magnitudes is called a transfer characteristic. FIG. 4 shows a graph of a typical transmission line's transfer characteristic (404). FIG. 3 shows the impedance of the transmission line increasing as the frequency of the data signal increases. Accordingly, FIG. 4 shows the transfer function decreasing as the frequency of the data signal increases.

A typical signal may include multiple frequency components. Each frequency component will be subjected to a different impedance on a transmission line, due to the frequency-dependent nature of the transmission line's impedance characteristic. Accordingly, each frequency component may be attenuated differently than other frequency components.

An example of an ideal data signal (510) is shown in FIG. 5A. A midline (512) is shown that serves to define the change in the value of the data signal (510). In the lower region (516), the data signal has a value of “0.” In the upper region (514), the data signal has a value of “1.” This type of digital scheme with a mid-line (512) is referred to as a single-end signal design.

FIG. 5B shows a more realistic view (518) of the waveform of the digital signal (510). The mid-line (512) as well as the upper (514) and lower (516) regions are the same. However, high frequency components of the signal (518) are subjected to some suppression of their peak value. The attenuation is particularly pronounced in the case of a single “1” in a field of “0”s. In some instances, the attenuated signal barely reaches the mid-line (512), which results in a very low probability of detection. In a single-end signal design, the probability of detection is determined by how far above or below a mid-line voltage potential the data signal's voltage potential is when the signal is latched.

With a typical signal that includes both high and low frequency signal components, the superposition of an unattenuated low frequency signal component with attenuated high frequency signal components causes intersymbol interference that reduces the maximum frequency at which the system can operate. The problem is not so much the magnitude of the attenuation as it is the interference caused by the frequency-dependent nature of the attenuation.

High frequency components are attenuated, so transition times are long. A transition time is the time it takes for a signal to transition from one value to another (i.e., from a “0” to a “1” or from a “1” to a “0”) and is determined by the resistive and capacitive elements of the transmission line's impedances (e.g., 206 and 208 shown in FIG. 2). The longer a transition time, the longer a receiving IC must wait to latch the data signal in order to have an acceptable probability of detection. The frequency with which the data signal may be latched determines a data transmission speed, which, in turn, determines how fast data can be transmitted on the transmission line.

A conventional solution to the problem of intersymbol interference is equalization of the signal by emphasizing the high frequency signal components of the data signal at the transmitting IC. Emphasizing a signal component is the opposite of attenuating a signal component. FIG. 6 shows a transmission line's transfer characteristic (604) and an emphasizing filter's transfer characteristic (602). As a frequency of a data signal increases, the transmission line increasingly attenuates the data signal. Conversely, as the frequency of the data signal increases, an emphasizing filter increasingly emphasizes the signal. The emphasizing filter is designed to cancel the effects of the transmission line's transfer characteristic (604) so that the overall frequency response (606) of the combination of the transmission line and the pre-emphasizing filter is flat. The overall frequency response (606) may be equal to the product of the transmission line's transfer characteristic (604) and the pre-emphasizing filter's transfer characteristic (602).

### SUMMARY OF INVENTION

According to one aspect of the present invention, an apparatus comprises a printed circuit board; a transmitter arranged to transmit a data signal on a transmission line disposed on the printed circuit board; and a filter operatively connected to the transmission line, where the filter is arranged to attenuate a low frequency signal component of the data signal.

According to one aspect of the present invention, a method for reducing intersymbol interference on a transmission line comprises transmitting a data signal on the transmission line, where the transmission line is disposed on a printed circuit board; and attenuating a low frequency signal component of a data signal on the transmission line.

According to one aspect of the present invention, an apparatus comprises means for transmitting a data signal on a transmission line disposed on a printed circuit board; and means for attenuating a low frequency signal component of a data signal.

### BRIEF DESCRIPTION OF DRAWINGS

FIG. 1 shows a prior art computer system.

FIG. 2 shows a prior art system for communication between integrated circuits.

FIG. 3 shows a graph of an impedance characteristic of a transmission line.

FIG. 4 shows a graph of a transfer characteristic of a transmission line

FIGS. 5a and 5b show an ideal digital signal and a realistic digital signal respectively.

FIG. 6 shows a prior art graph of transfer characteristics.

FIG. 7 shows a system for communication between integrated circuits in accordance with an embodiment of the present invention.

FIG. 8 shows a graph of impedances in accordance with an embodiment of the present invention.

FIG. 9 shows a graph of transfer characteristics in accordance with an embodiment of the present invention.

FIG. 10 shows a non-filtered digital signal and a filtered digital signal in accordance with an embodiment of the present invention.

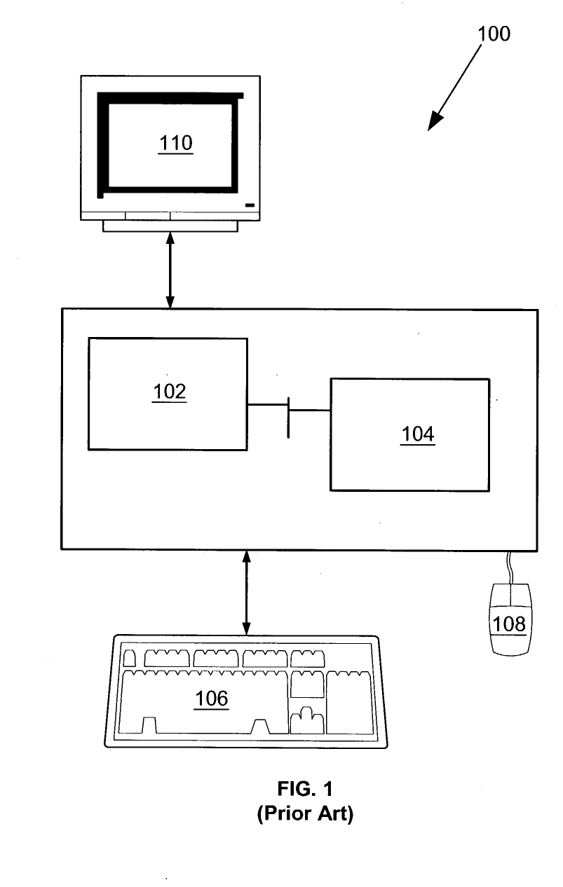

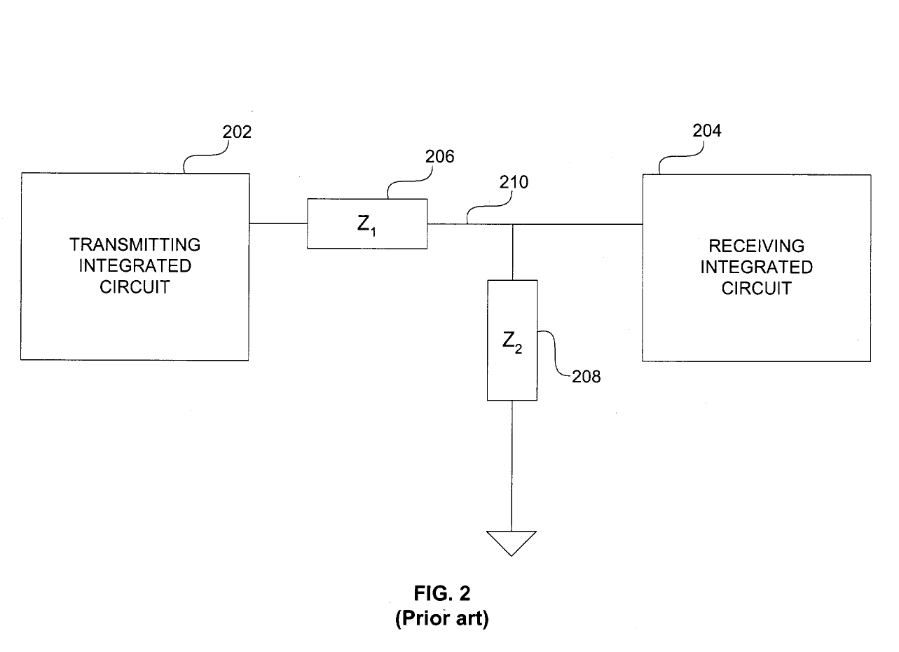

### DETAILED DESCRIPTION

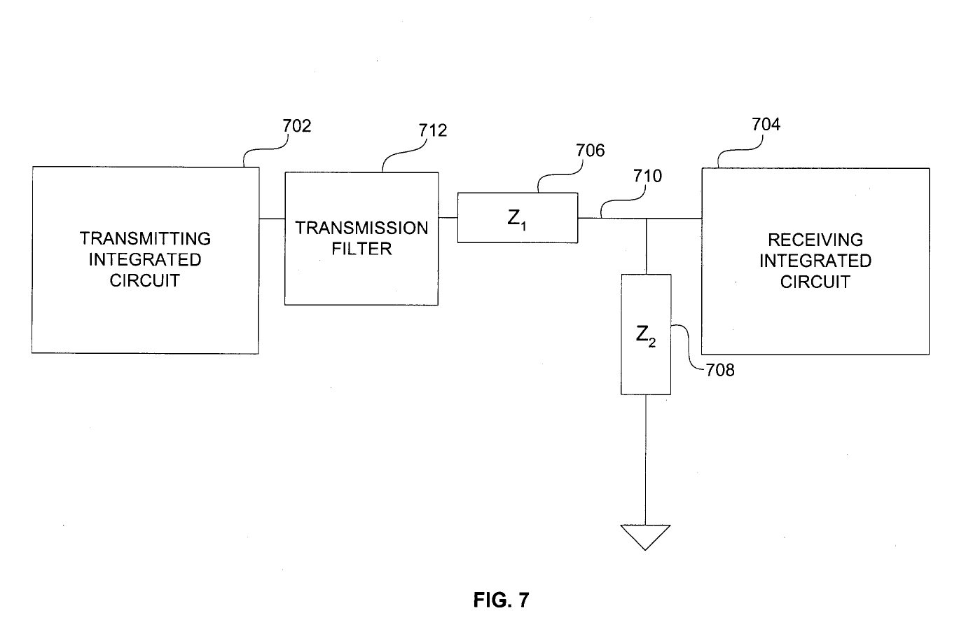

Embodiments of the present invention relate to a technique for increasing the speed at which data may be transmitted on a transmission line by equalizing the transmission line. FIG. 7 shows a block diagram of an exemplary embodiment of the present invention. A transmitting IC (702) transmits a data signal on a transmission line (710) to a receiving IC (704). The transmission line (710) includes impedances (706, 708) that represent parasitic impedances of the transmission line (710). The impedances (706, 708) may include resistive, capacitive, and inductive elements. The present invention includes a transmission filter (712) designed to attenuate low frequency components of the data signal on the transmission line (710). The filter (712) is operatively connected to the transmission line (710), and disposed between the transmitting IC (702) and the receiving IC (704). The filter (712) may be disposed on a printed circuit board on which the transmitting IC (702) and/or the receiving IC (704) may also be disposed.

In one or more embodiments of the present invention, the transmission filter (712) may be a high-pass filter which allows high frequency components of the data signal to pass relatively unaffected, while low frequency components of the data signal are attenuated. In one or more embodiments of the present invention, the transmission filter (712) may be an analog circuit, and may include resistors, capacitors, inductors, or any combination of the three.

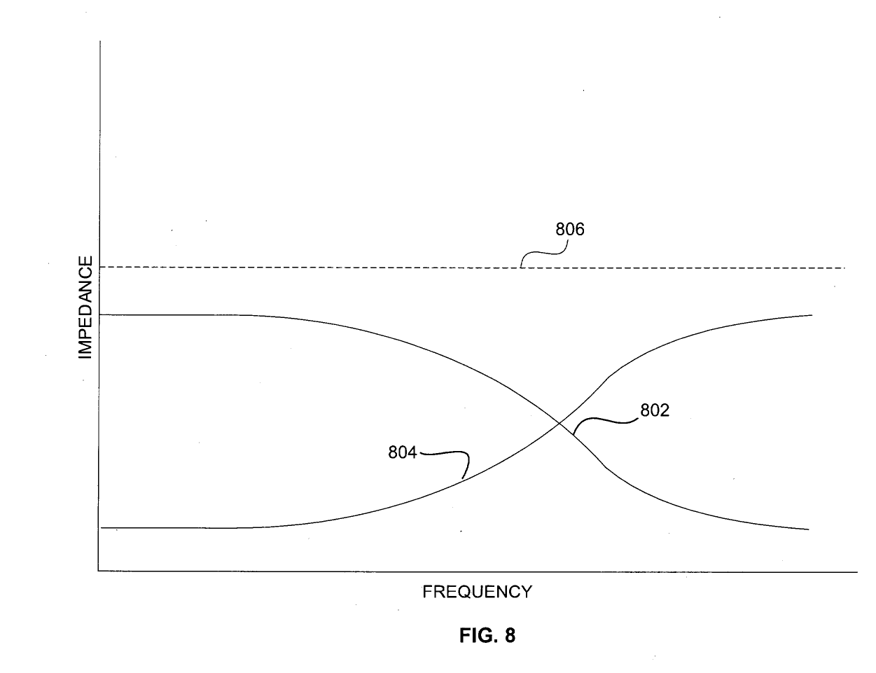

FIG. 8 shows a transmission line's impedance characteristic (804) and a transmission filter's impedance characteristic (802) in accordance with an embodiment of the present invention. As a frequency of a data signal increases, the transmission line's impedance to that signal also increases. Conversely, as the frequency of the data signal decreases, the transmission filter's impedance increases. The transmission filter is designed to cancel the effects of the transmission line's frequency-dependent impedance characteristic (804) so that the overall impedance characteristic (806) of the combination of the transmission line and the transmission filter is constant. The overall impedance characteristic (806) may be equal to the sum of the transmission line's impedance characteristic (804) and the transmission filter's impedance characteristic (802).

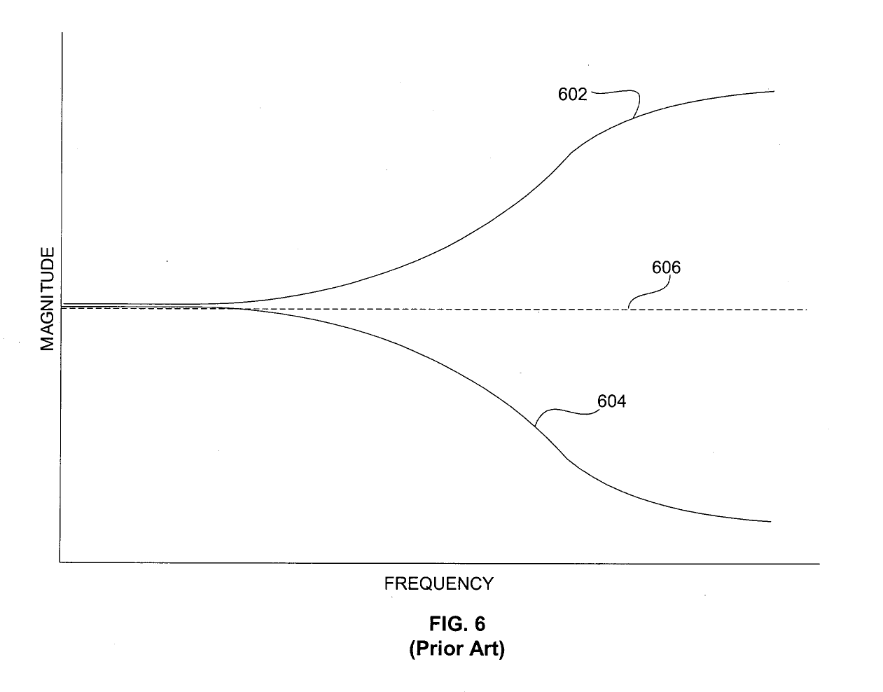

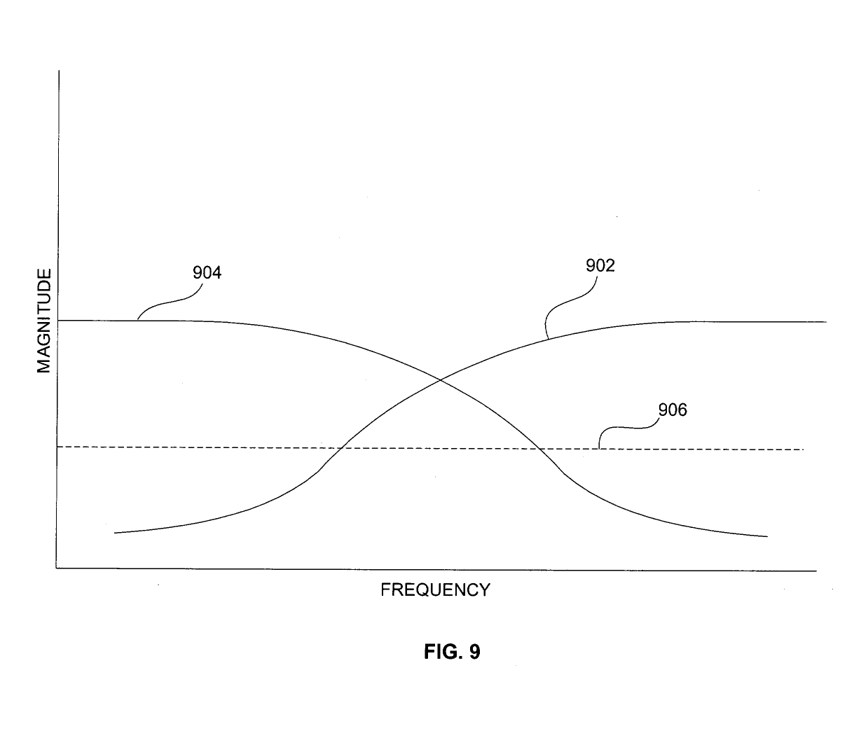

FIG. 9 shows a transfer characteristic (904) of a transmission line and a transfer characteristic (902) of a transmission filter in accordance with an exemplary embodiment of the present invention. As a frequency of a data signal increases, the transmission line increasingly attenuates the data signal. Conversely, as the frequency of the data signal decreases, the transmission filter increasingly attenuates the data signal. This is opposite of the filter whose effects are described by FIG. 6. Instead of increasingly emphasizing high frequency signal components, the present invention increasingly attenuates low frequency signal components. The transmission filter is designed to cancel the effects of the transfer characteristic (904) of the transmission line so that the overall frequency response (906) of the combination of the transmission line and the transmission filter is flat. The overall frequency response (906) may be equal to the product of the transfer characteristic (904) of the transmission line and the transfer characteristic (902) of the transmission filter.

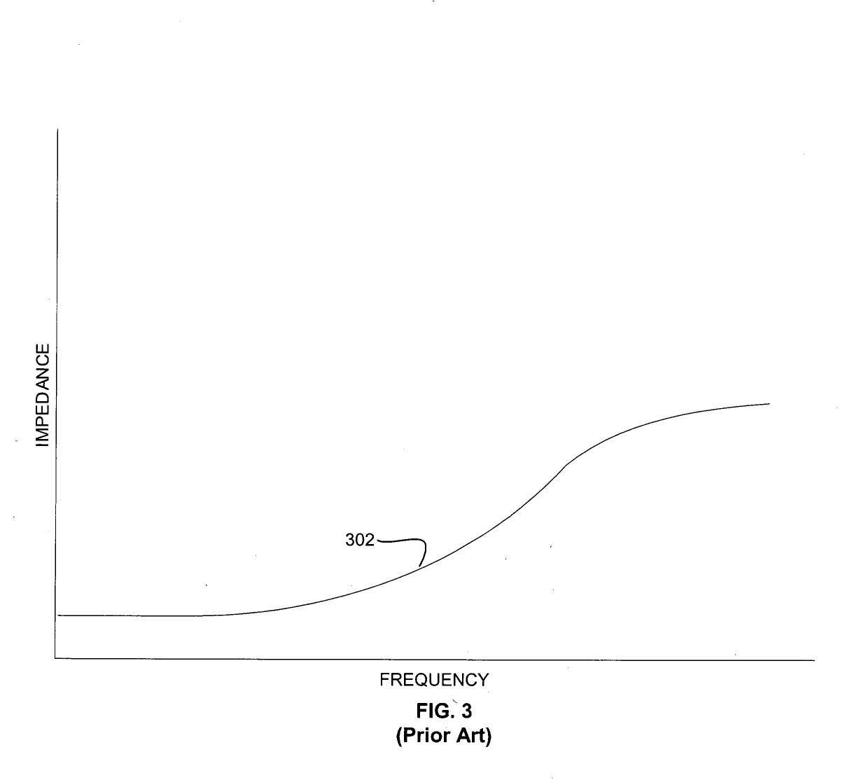

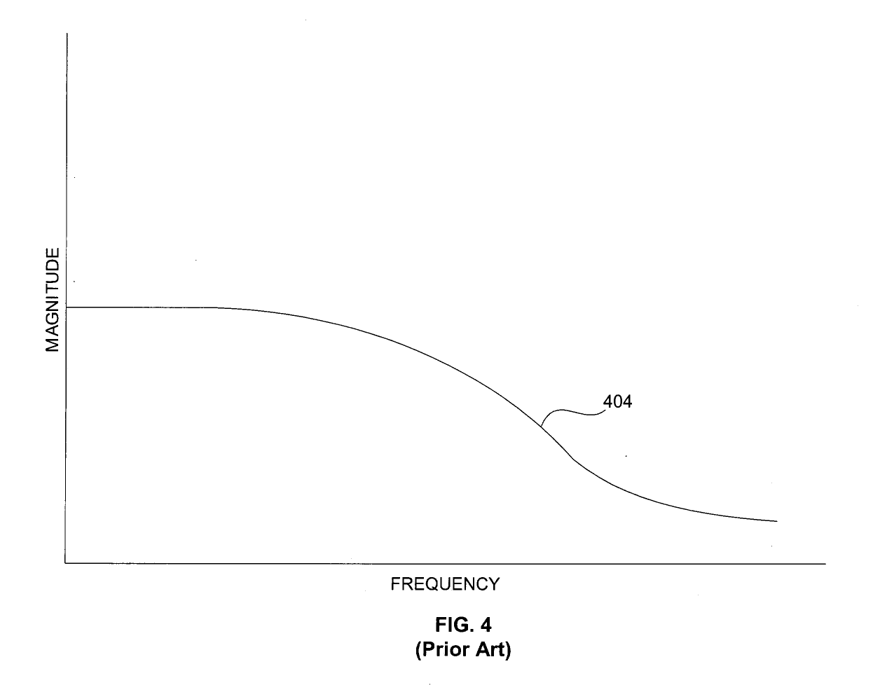

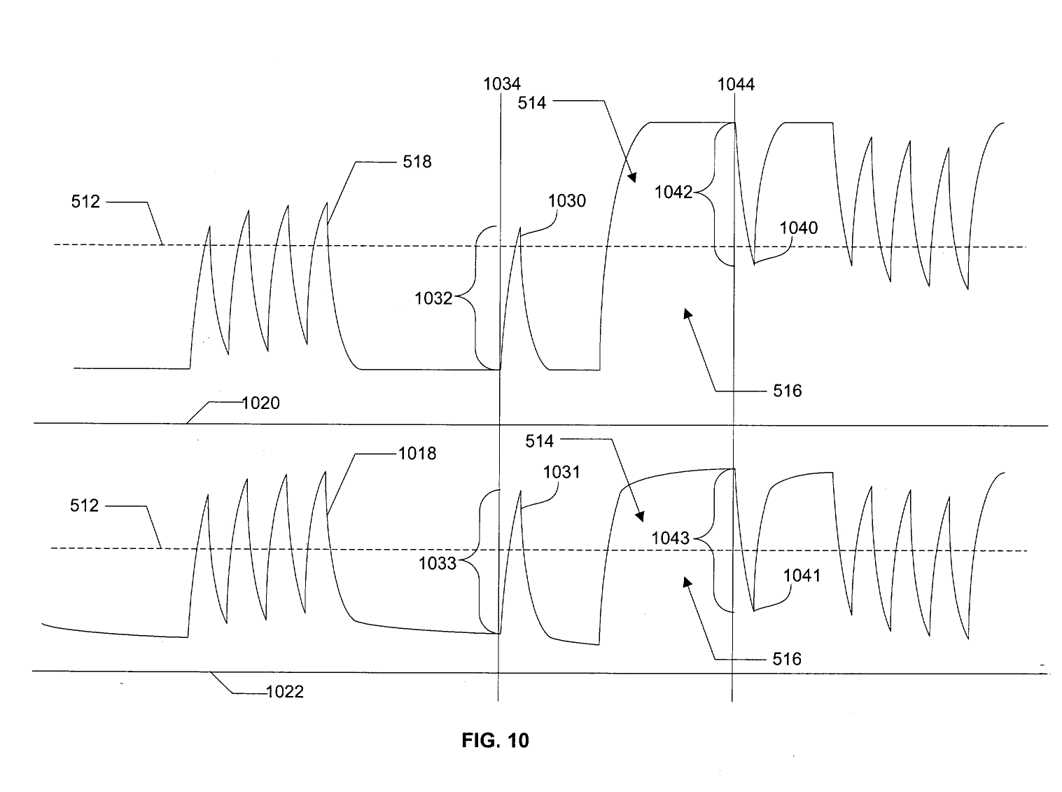

FIG. 10 shows a filtered waveform (1018) in accordance with an embodiment of the present invention. Like items from FIG. 3 are shown with like reference numbers. Lines (1020) and (1022) show the maximum and minimum voltage potentials, respectively, achieved by a non-filtered signal (518). Effects of the transmission filter can be seen in the filtered waveform (1018). Long series of “1”s or “0”s take substantially longer to reach the maximum value (1020) or minimum value (1022), respectively, than they do in the non-filtered waveform (518). A single “1” in a long string of “0”s (e.g., 1030 and 1031) has the same voltage potential difference (1032 and 1033, respectively) in both waveforms. However, the filtered signal's (1018) voltage potential at time (1034) is greater than the voltage potential of the non-filtered signal (518), and relatively greater than the mid-line (512). Accordingly, detection of a “1” is more probable for the filtered signal (1018) than for the non-filtered signal (518).

Similarly, a single “0” in a long string of “1”s (e.g., 1040 and 1041) has the same voltage potential difference (1042 and 1043, respectively) in both waveforms. However, the filtered signal's (1018) voltage potential at time (1044) is less than the voltage potential of the non-filtered signal (518), and relatively less than the mid-line (512). Accordingly, detection of a “0” is more probable for the filtered signal (1018) than for the non-filtered signal (518).

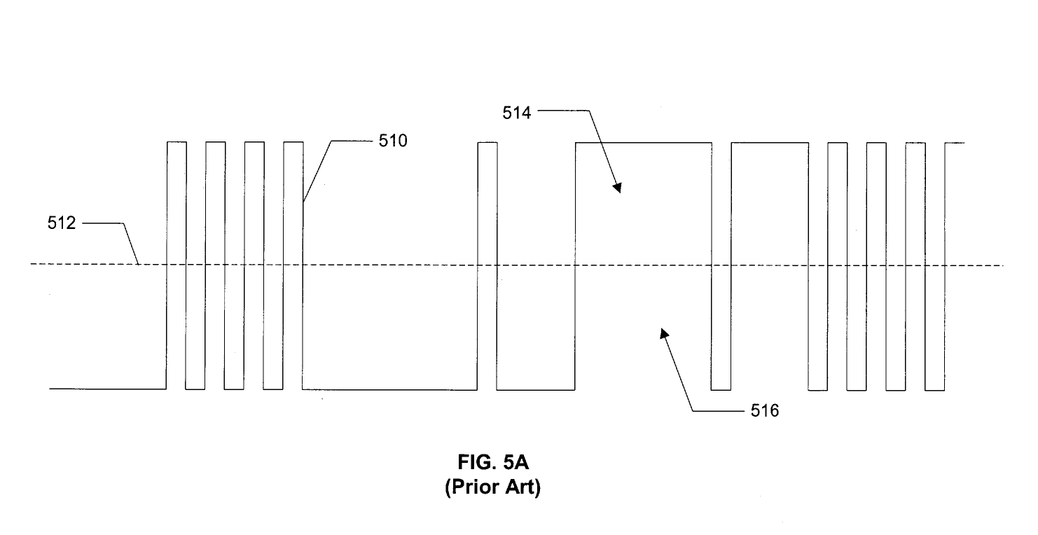

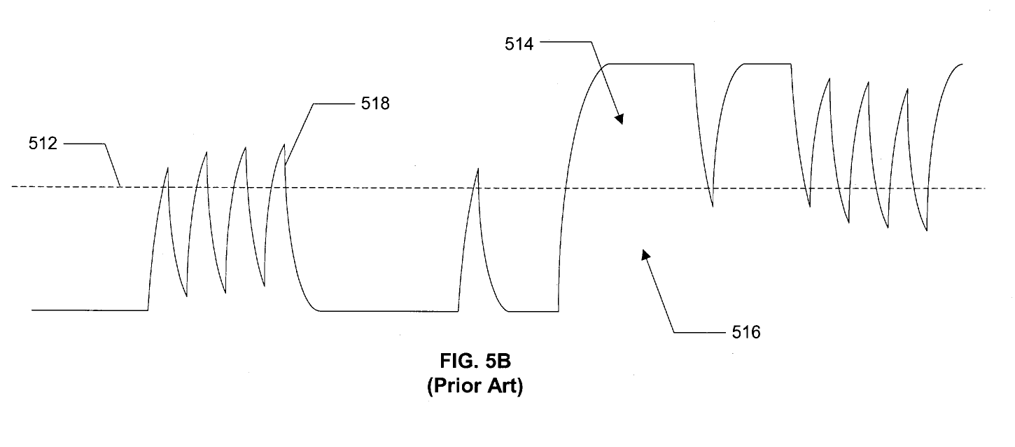

A differential transmission system differs from a single-end transmission system in that two signals are transmitted on two transmission lines, such that the signals are complements of one another. That is, when one signal's value is “1,” the other signal's value is “0.” There may not be a mid-line (e.g. 512 in FIG. 5B) as in the single-end transmission system. A differential transmission system may also be affected by intersymbol interference, and the intersymbol interference of the differential transmission system may also be corrected by embodiments of the present invention.

Advantages of the present invention may include one or more of the following. In one or more embodiments, the present invention may increase the reliability of a data transmission system by increasing the probability that a particular bit will be correctly detected. In one or more embodiments, the present invention may dissipate less power than conventional solutions to the problem of intersymbol interference. In one or more embodiments, the present invention may increase the maximum rate of data transfer on a transmission line. In one or more embodiments, a filter disposed on a printed circuit board may allow tuning of the filter dependent on characteristics of the printed circuit board. Accordingly, if characteristics of the printed circuit board change, the filter may be tuned without redesigning the transmitting IC or the receiving IC.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An apparatus, comprising:
a printed circuit board;
a transmitter arranged to transmit a data signal on a transmission line disposed on the printed circuit board; and
a filter operatively connected to the transmission line, wherein the filter is arranged to attenuate a low frequency signal component of the data signal.

2. The apparatus of claim 1, wherein the transmission line is arranged to attenuate a high frequency signal component of the data signal more than a low frequency signal component of the data signal.

3. The apparatus of claim 1, wherein the filter is arranged to increase an impedance of the transmission line for the low frequency signal component of the data signal.

4. The apparatus of claim 1, wherein the filter is a high pass filter.

5. The apparatus of claim 1, wherein the filter is disposed on the printed circuit board.

6. The apparatus of claim 1, wherein the filter is an analog circuit.

7. The apparatus of claim 1, wherein the filter comprises a resistor.

8. The apparatus of claim 1, wherein the filter comprises a capacitor.

9. The apparatus of claim 1, wherein the filter comprises an inductor.

10. The apparatus of claim 1, further comprising a receiver arranged to receive a filtered data signal.

11. The apparatus of claim 1, wherein the filter is disposed between the transmitter and a receiver.

12. The apparatus of claim 1, further comprising:
a second transmitter arranged to transmit a second data signal on a second transmission line disposed on the printed circuit board; and
a second filter operatively connected to the second transmission line, wherein the second filter is arranged to attenuate a low frequency signal component of the second data signal.

13. The apparatus of claim 12, wherein the second data signal comprises a complement of the first data signal.

14. A method for reducing intersymbol interference on a transmission line, comprising:
transmitting a data signal on the transmission line, wherein the transmission line is disposed on a printed circuit board; and
attenuating a low frequency signal component of the data signal on the transmission line.

15. The method of claim 14, wherein the attenuating comprises increasing an impedance of the transmission line for the low frequency signal component of the data signal.

16. The method of claim 14, wherein the attenuating comprises high-pass filtering the data signal.

17. The method of claim 14, wherein the attenuating is dependent on a frequency characteristic of the transmission line.

18. An apparatus, comprising:
means for transmitting a data signal on a transmission line disposed on a printed circuit board; and
means for attenuating a low frequency signal component of a data signal.

19. The apparatus of claim 18, wherein the means for attenuating comprises:
means for increasing an impedance of a low frequency signal component of the data signal.

20. The apparatus of claim 18, wherein the means for attenuating comprises:
means for high-pass filtering the data signal.
